(19) United States
(12) Patent Application Publication
(10) Pub. No.: US 2020/0321918 A1
(43) Pub. Date: Oct. 8, 2020

(54) INTEGRATED DOHERTY AMPLIFIER

(71) Applicant: SUMITOMO ELECTRIC DEVICE INNOVATIONS, INC., Kanagawa (JP)

(72) Inventor: Andrey GREBENNIKOV, Herts (GB)

(73) Assignee: SUMITOMO ELECTRIC DEVICE INNOVATIONS, INC.

(21) Appl. No.: 16/834,475

(22) Filed: Mar. 30, 2020

Related U.S. Application Data
(60) Provisional application No. 62/830,014, filed on Apr. 5, 2019.

(51) Int. Cl. H03F 1/02; H03F 1/56; H03F 3/68

(52) U.S. Cl. CPC H03F 1/0288; H03F 1/565; H03F 2200/423; H03F 2200/375; H03F 3/68

(57) ABSTRACT

An integrated Doherty amplifier based on a multichip module structure is disclosed. The amplifier comprises an input integrated passive die including a Wilkinson power divider, a phase compensation circuit and input matching circuits for the main and peaking amplifiers based on lumped components, the active GaN HEMT die including the main device, a peaking device and a bondwire inductor connected between the drain terminals of the main and peaking devices, and an output matching network including a two-section matching circuit with low-pass and high-pass matching section operating as an impedance-transforming bandpass filter and a dc-feed power supply circuit based on lumped components and microstrip lines.

### CROSS-REFERENCE TO RELATED APPLICATIONS

This application claims the priority under 35 U.S.C. § 119 of U.S. Provisional Application Ser. No. 62/830,014, filed on Apr. 5, 2019; the contents of which are relied upon and incorporated herein by reference in its/their entirety.

### TECHNICAL FIELD

The present application relates to an integrated Doherty amplifier.

### BACKGROUND

A classical Doherty amplifier architecture incorporates the main amplifier and peaking amplifier separated by a quarter-wavelength transmission line located in the main amplifying path. Both the main and peaking amplifying paths usually include the input matching circuit and load network each to operate in a 50-Ω environment. The input power from the source is divided in two equal parts by the input splitter for symmetrical Doherty structure. The quarter-wavelength transmission line provides impedance transformation from 25 Ω into 100 Ω seen by the main amplifier at low power level (less than −6 dBc from the saturated power) when the peaking amplifier is turned off. The quarter-wavelength transmission line at the input of the peaking amplifier is required to compensate for the 90-degree phase shift caused by the quarter-wavelength transmission line at the output of the main amplifying path. The output quarter-wavelength line with the characteristic impedance Z₀=(25×50)^{1/2}=35.3 Ω is required to match the standard load impedance of 50 Ω when both the main and peaking amplifying paths deliver maximum power when each of which is designed in a 50-Ω environment.

Despite the presence of two additional quarter-wavelength transmission lines, one at the input for phase compensation and the other at the output operating as an impedance transformer, a Doherty amplifier can be considered as a very attractive good candidate for circuit integration using both the hybrid and monolithic implementations. In this case, to minimize size and cost and to simplify the design complexity of a high-power integrated Doherty amplifier implemented in standard discrete package, a π-type low-pass and high-pass lumped LC circuits to equivalently replace the corresponding quarter-wavelength lines can be used. For example, the quarter-wavelength impedance transformer can be equivalently replaced by a π-type low-pass circuit formed by the device drain-source capacitances and a bonding wire placed between the device drains [Doherty amplifier, U.S. Pat. No. 7,800,448, Sep. 21, 2010]. FIG. 1 shows the schematic circuit of the prior art of an integrated Doherty amplifier where the input phase shifter is equivalently replaced by the π-type low-pass circuit formed by the device gate-source capacitances and a bonding wire placed between the device gates [Integrated Doherty amplifier, U.S. Pat. No. 8,228,123, Jul. 24, 2012]. Here, an additional L-type LC matching section is used at the input and an additional low-pass L-type LC matching section is used at the output where the inductors are represented by bonding wires. However, generally these single-section matching networks can only provide the complex-conjugate matching with some intermediate input and output impedances rather than with 50-ohm source and load, especially for high power device having extremely small input impedances and requiring sufficiently low output load impedances. Besides, there is no isolation between the inputs of the main and peaking amplifying paths, where the main and peaking devices are operated with different bias voltages, Class-AB bias for main device and Class-C bias for peaking device. Also, for wideband modulated signals which are used in modern 4/5G cellular systems, a single low-pass matching section at the output of an integrated Doherty amplifier cannot provide sufficient suppression of the harmonic and intermodulation components above operating bandwidth and has no effect on modulation and intermodulation components below operating bandwidth.

FIG. 1 shows the schematic block of a conventional Doherty amplifier architecture, which incorporates the carrier amplifier (CA) and peaking amplifier (PA) separated by a quarter-wavelength transmission line located in the CA path [1]. Both the PA and CA may include the input matching circuit and load network each to operate in a 50-Ω environment. The input power of radio frequency (RF) signal from the source is evenly divided in two equal parts by the input splitter for symmetrical Doherty structure. The quarter-wavelength transmission line provides impedance transformation from 25 Ω into 100 Ω seen by the CA at low power level (less than −6 dBc from the saturated power) when the PA is turned off. The quarter-wavelength transmission line at the input of the PA is required to compensate for the 90-degree phase shift caused by the quarter-wavelength transmission line at the output of the CA. The output quarter-wavelength line with the characteristic impedance Z₀=(25×50)^{1/2}=35.3 Ω is required to match the standard load impedance of 50 Ω when both the CA and PA deliver maximum power when each of which is designed in a 50-Ω environment. However, the conventional Doherty amplifier has a significant disadvantage when its power gain drops by 3 dB at lower output power level when the PA is turned off. This is because the half an input power continues to be delivered to the PA input due to 3-dB input splitter.

To split signals at the Doherty amplifier input between the main and peaking amplifying paths with sufficient isolation between these amplifying paths and minimum insertion loss, it is necessary to use a hybrid coupler. The simplest two-way coupler which can be used for both symmetrical and asymmetrical Doherty structures and can be easy implemented into the integrated Doherty amplifier is a Wilkinson power divider. FIG. 2A shows the planar structure of the Wilkinson power divider which consists of two quarter-wavelength microstrip lines connected in parallel at the input bonding pad (IBP) and the planar ballast resistor connected between the output bonding pads (OBP1 and OBP2), where the characteristic impedances Z₁ and Z₂ are equal for symmetrical Doherty amplifier configuration and are unequal for asymmetrical Doherty amplifier structure. Despite its small dimensions and simple construction, such a power divider provides sufficient isolation between the output ports over a sufficiently wide frequency bandwidth when equal power division is provided due to symmetrical configuration with R₀=2Z₀ and Z₁=Z₂=Z₀(2)^{1/2}, where Z₀ is the characteristic source and load impedance. For asymmetric Doherty amplifier with unequal power split, the characteristic impedances Z₁ and Z₂ and ballast resistor R₀ are calculated from

$$\begin{matrix}{Z}_{1} = K {Z}_{0} \sqrt{K + \frac{1}{K}} & ( 1 ) \\ {Z}_{2} = \frac{{Z}_{0}}{K} \sqrt{K + \frac{1}{K}} & ( 2 ) \\ {R}_{0} = {Z}_{0} ( K + \frac{1}{K} ) & ( 3 )\end{matrix}$$

where K is the voltage split ratio. Such a Wilkinson power divider can also provide an impedance matching to eliminate additional matching sections by proper selection of the transmission-line characteristic impedance Z₀ for known input impedance Zᵢₙ or output impedance Zₒᵤₜ to invert impedances according to

Z₀=\sqrt{ZᵢₙZₒᵤₜ}, (4)

where Z₀ is the characteristic impedance of the transmission line.

To minimize the inherently high substrate loss and increase the level of integration of the Wilkinson power divider, the quarter-wavelength transmission lines can be fully substituted by their lumped equivalents. By considering the transmission ABCD-matrices for a quarter-wavelength transmission line and a π-type low-pass lumped circuit consisting of a series inductance and two shunt capacitors and equating the corresponding elements of both matrices, the ratio between the circuit parameters can be written as

$${Z}_{0} ω C = \frac{{Z}_{0}}{ω L} = 1 \qquad ( 5 )$$

where Z₀ is the characteristic impedance of the quarter-wavelength transmission line. For unequal Wilkinson power divider, it is necessary to calculate the corresponding inductances and capacitances separately (C₁L₁ and C₂L₂) for each transmission line by substituting Z₁ and Z₂ instead of Z₀ into Eq. (5).

In a classical Doherty amplifier with a Wilkinson power divider to split input signal between the main and peaking amplifying paths, an additional quarter-wavelength transmission line at the input of the peaking amplifier is required to compensate for the 90° phase shift caused by the quarter-wavelength transmission line at the output of the main amplifier. However, generally its electrical length may differ from 90° because the input reactance of the main and peaking devices varies depending on the gate bias voltage. In this case, the ratio of the circuit parameters corresponding to the transmission line and its π-type low-pass lumped equivalent shown in FIG. 2b and given by Eq. (5) can be rewritten as a function of electrical length θ as

$$\begin{matrix}ω L = {Z}_{0} sin θ & ( 6 ) \\ ω C = \frac{1 - cos θ}{{Z}_{0} sin θ} . & ( 7 )\end{matrix}$$

### SUMMARY

The present invention provides an integrated Doherty amplifier based on a multichip module structure which comprises an input integrated passive die including a Wilkinson power divider, a phase compensation circuit and input matching circuits for the main and peaking amplifiers based on lumped components, the active GaN HEMT die including the main device, a peaking device and a bondwire inductor connected between the drain terminals of the main and peaking devices, and an output matching network including a two-section matching circuit with low-pass and high-pass matching section operating as an impedance-transforming bandpass filter and a dc-feed power supply circuit based on lumped components and microstrip lines.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 shows a circuit schematic of the prior art of an integrated Doherty amplifier;

FIG. 2A shows a planar structure of a Wilkinson power divider and its equivalent, and FIG. 2B shows a planar structure of a transmission line and its equivalent;

FIG. 3 shows a circuit schematic of a proposed integrated Doherty amplifier;

FIG. 4 shows an implementation of the proposed integrated Doherty amplifier of FIG. 3;

FIG. 5 shows an implementation of another embodiment of the proposed integrated Doherty amplifier;

FIG. 6 shows an implementation of another embodiment of the proposed integrated Doherty amplifier;

FIG. 7 shows another circuit schematic of a proposed integrated Doherty amplifier; and

FIG. 8 shows an implementation of the proposed integrated Doherty amplifier of FIG. 7.

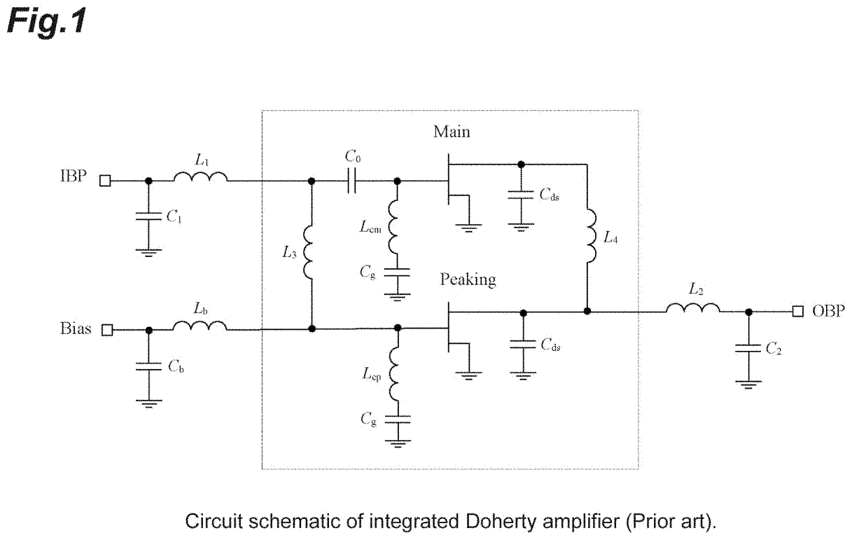

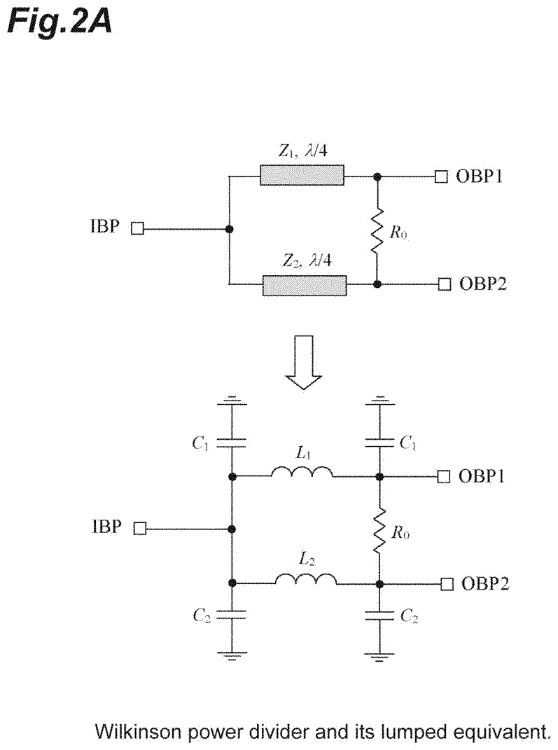

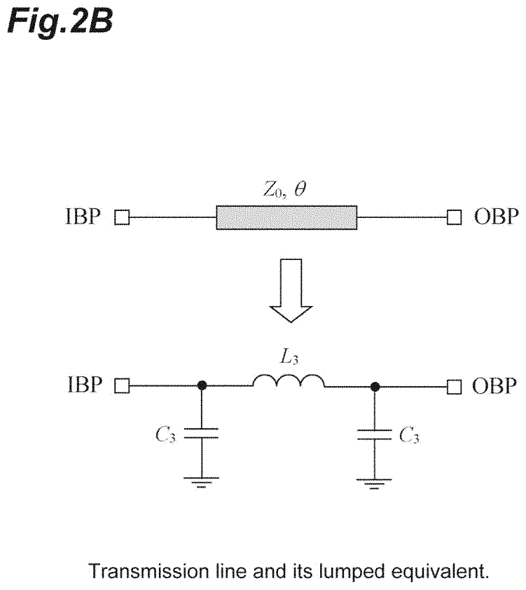

### DETAILED DESCRIPTION

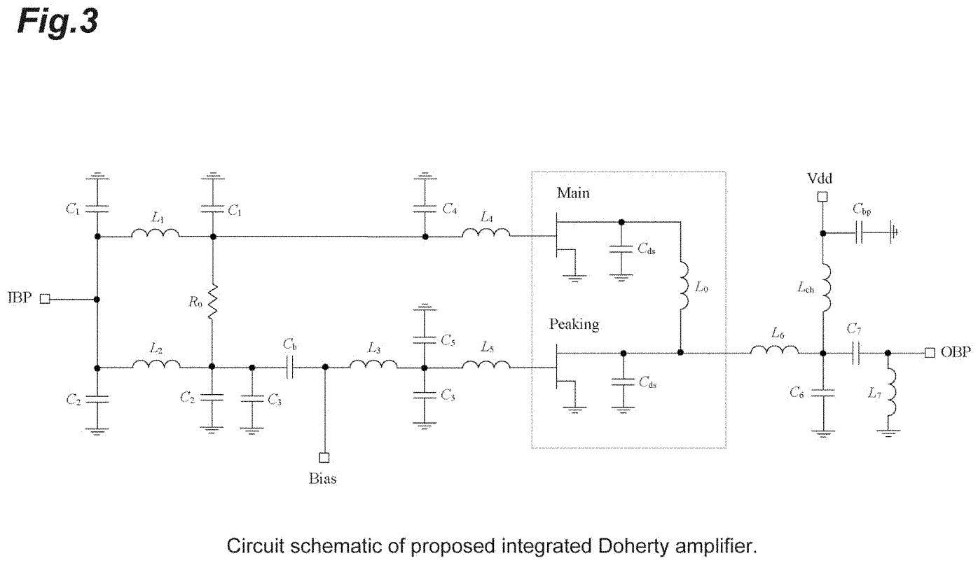

FIG. 3 shows the circuit schematic of proposed integrated Doherty amplifier with improved insertion loss, isolation between the main and peaking amplifiers, and spurious suppression. Here, the impedance inverter consists of two drain-source capacitances C_{ds} (capacitances C_{ds} are different if the main and peaking devices have different numbers of cells) and inductor L₄ which is implemented as a bonding wire, the output impedance transformation is provided by a two-section matching circuit (an output combiner) representing a band-pass filter structure with the first low-pass matching section (L₆C₆) to suppress harmonic and intermodulation components above operating bandwidth and the second high-pass matching section (C₇L₇) to suppress the modulation, intermodulation, and subharmonic components below operating bandwidth. The two-section matching circuit combines outputs of main and peaking devices each provided through the offset transmission line (L₀ or L₆).

The choke inductor L_{ch} and the bypass capacitor C_{bp} are used to connect the RF amplifying path with a dc-feed power supply, and the value of the inductor L_{ch} can be adjusted by varying the value of the shunt capacitor C₆.

In addition to the lumped Wilkinson power divider (C₁L₁C₁-C₂L₂C₂-R₀) and the phase compensation line (C₃L₃C₃), two input low-pass matching sections (C₄L₄ for the main device and C₅L₅ for the peaking device) are used where L₄ and L₅ are implemented by bonding wires connecting the device gate to an external input circuit.

The capacitor C_{b} is a dc-blocking capacitor to isolate a dc-bias circuit for the peaking device from an RF input path.

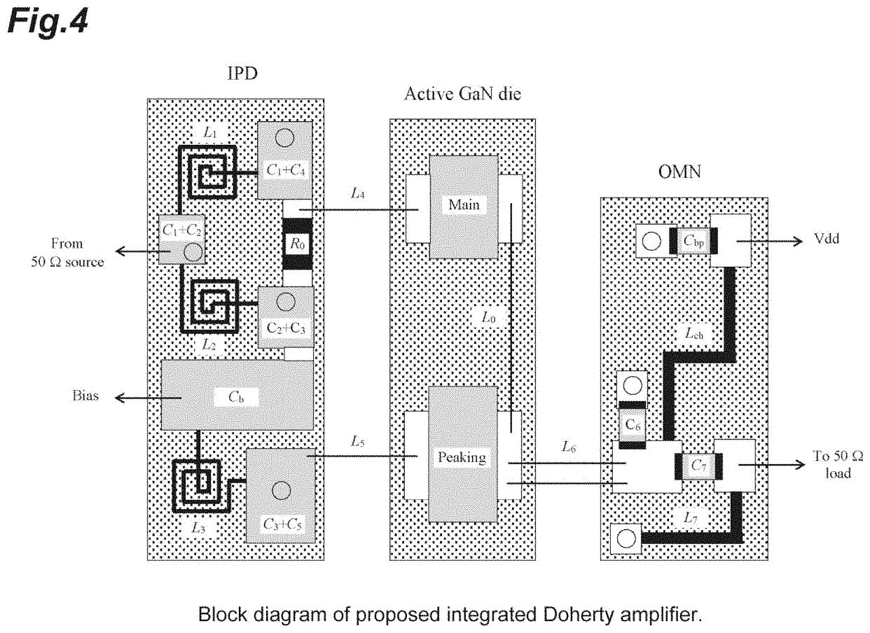

FIG. 4 shows the implementation of the proposed integrated Doherty amplifier where the main and peaking devices are located on separate active die (semiconductor chip) using GaN HEMT technology, the integrated passive die (IPD) is used for an input circuit including the Wilkinson power divider, and the output matching network (OMN) is used to implement the output matching circuit including a dc-feed power supply circuit.

The key benefits of the IPD technology using gallium arsenide or silicon high-resistivity substrate to implement multiple passive components such as inductors, capacitors, and resistors on a single substrate are a competitive cost structure, a small form factor, and reduced power losses. In view of high dc supply voltage (up to 50 V) and high peak output power (several tens of watt), the best choice for OMN implementation with minimum insertion loss is to use the ceramic or laminate substrate. The magnetic coupling between the bondwire inductances L₀ and L₆ is minimized due to their orthogonal orientation to each other.

An input IPD comprises the combined metal-insulator-metal (MIM) series capacitor C₁+C₂, series spiral inductors L₁ and L₂, the combined shunt MIM capacitors C₁+C₄ and C₂+C₃ grounded through substrate vias, the ballast resistor R₀, the blocking series MIM capacitor C_{b}, the series spiral inductor L₃ and the combined shunt MIM capacitor C₃+C₅ grounded through substrate via.

The series bondwire inductors L₄ and L₅ represent the corresponding parts of the input low-pass matching sections directly connected to the gates of the main and peaking devices, respectively. The bondwire inductor L₀ directly connects the drains of the main and peaking devices as a part of the impedance inverter, whereas the bondwire inductor L₆ connected to the drain of the peaking device operates as a series inductor of the output low-pass matching section of a two-section OMN. One end of bondwire inductor L₀ is directly connected with the drain of the main device, and other end of bondwire inductor L₀ is directly connected with the drain of the peaking device. One end of bondwire inductor L₀ is also directly connected with one end of the bondwire inductor L₆.

An OMN also includes the chip capacitor C₆ (grounded through substrate via) as a shunt element of the low-pass matching section, and the series chip capacitor C₇ and shunt inductor L₇ (grounded through the substrate via) as elements of the high-pass matching section.

The combination of the low-pass and high-pass matching sections in a single matching network operates as an impedance-transforming bandpass filter to suppress the low-frequency and high-frequency intermodulation and harmonic components simultaneously. To improve the quality factors of the inductance and to reduce the insertion loss in the OMN, the shunt inductor L₇ and the choke inductor L_{ch} are implemented as short-length microstrip lines.

As an example, using the laminate substrate with dielectric permittivity of 3.5 and thickness of 0.5 mm, the lengths of the microstrip lines L_{ch} and L₇ when using two 20-W GaN HEMT devices for symmetrical Doherty structure (or 10 W and 30 W devices for 1:3 asymmetrical Doherty configuration) are equal to 3 mm and 2 mm, respectively, whereas the width of these microstrip lines are of 0.2 mm.

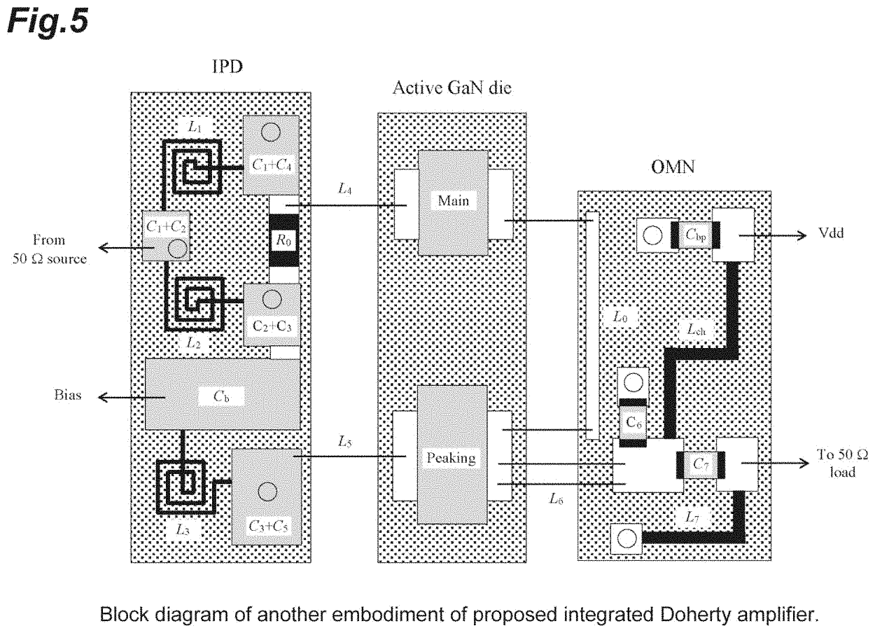

FIG. 5 shows another embodiment of the proposed integrated Doherty amplifier which is used when the bondwire L₀ is too long and cannot be physically implemented as a single bondwire between two device drains. In this case, a narrow microstrip line implemented on OMN can be used, whose length and width can be adjusted depending on the required overall inductance value for L₀. Each device drain from active GaN die is connected by short bondwire to the corresponding end of this microstrip line.

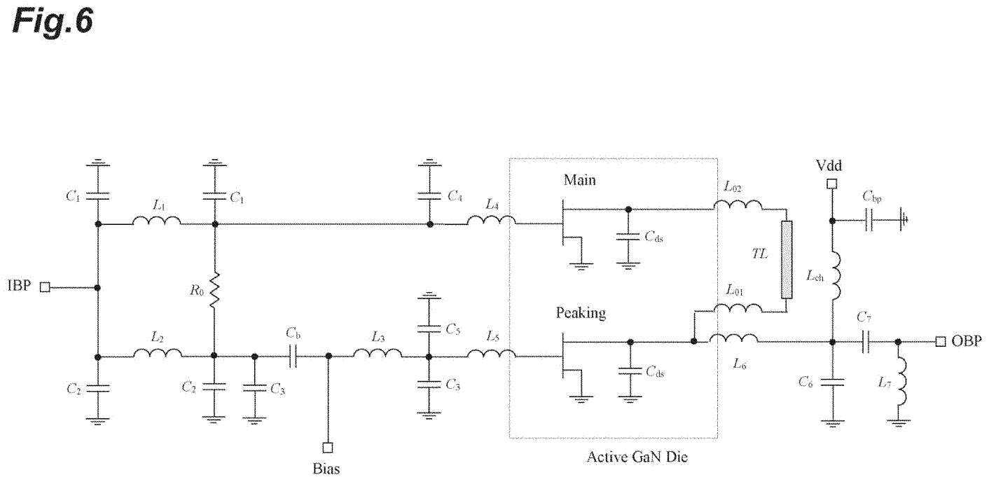

FIG. 6 shows the implementation of the proposed integrated Doherty amplifier where the main and peaking devices are located on separate active die using GaN HEMT technology, the narrow microstrip line TL and bondwire inductor L₀₁, bondwire inductor L₀₂ provided instead of the bondwire inductor L₀ in the implementation of the proposed integrated Doherty amplifier of FIG. 4.

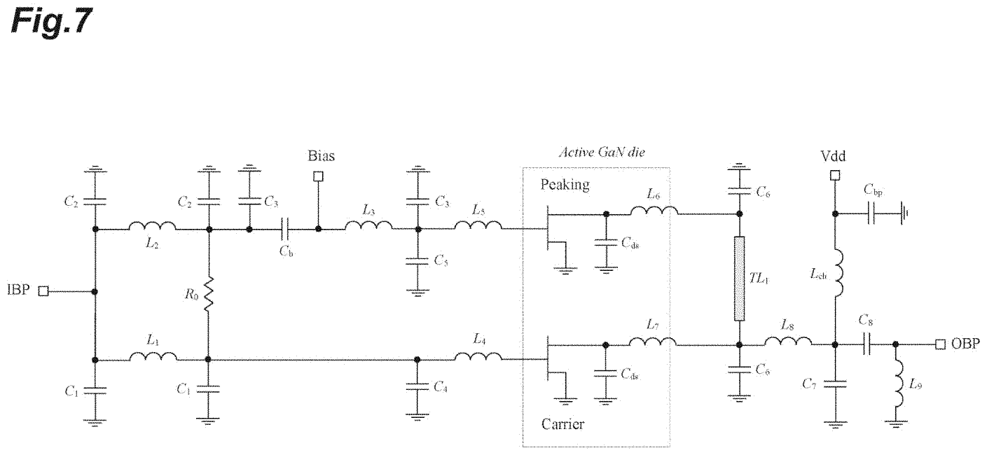

FIG. 7 shows the circuit schematic of the proposed integrated Doherty amplifier with improved insertion loss, high isolation between the carrier and peaking amplifier, and spurious suppression. Here, the impedance inverter in the peaking amplifying path consists of two equal grounded capacitors C₆ and transmission line TL₁, while the impedance transformation at the output of the carrier device is provided by the drain-source capacitance C_{ds} and bondwire inductor L₇ and at the output of the peaking device (at high-power region when the transistor is turned on) by the drain-source capacitance C_{ds} and bondwire inductor L₆ (capacitances C_{ds} are different if the carrier and peaking devices have different number of cells).

The output impedance transformation is provided by a two-section matching circuit representing a band-pass filter with the first low-pass matching section (L₈C₇) to suppress harmonic and intermodulation components above operating bandwidth and the second high-pass matching section (C₈L₉) to suppress the modulation, intermodulation, and subharmonic components below operating bandwidth.

The choke inductor L_{ch} and bypass capacitor C_{bp} are used to connect the RF amplifying path with dc-feed power supply, and the value of the inductor L_{ch} can be adjusted by varying the value of the shunt capacitor C₇ to optimize the size of the output matching network (OMN).

In addition to lumped Wilkinson divider (C₁L₁C₁-C₂L₂C2-R₀) and the phase compensation line (C₃L₃C₃), two input low-pass matching sections (C₄L₄ for carrier device and C₅L₅ for peaking device) are used where L₄ and L₅ are implemented by bonding wires connecting the corresponding device gate to external input circuit. The capacitor C_{b} is a dc-blocking capacitor to isolate dc-bias circuit for the peaking device from RF input path.

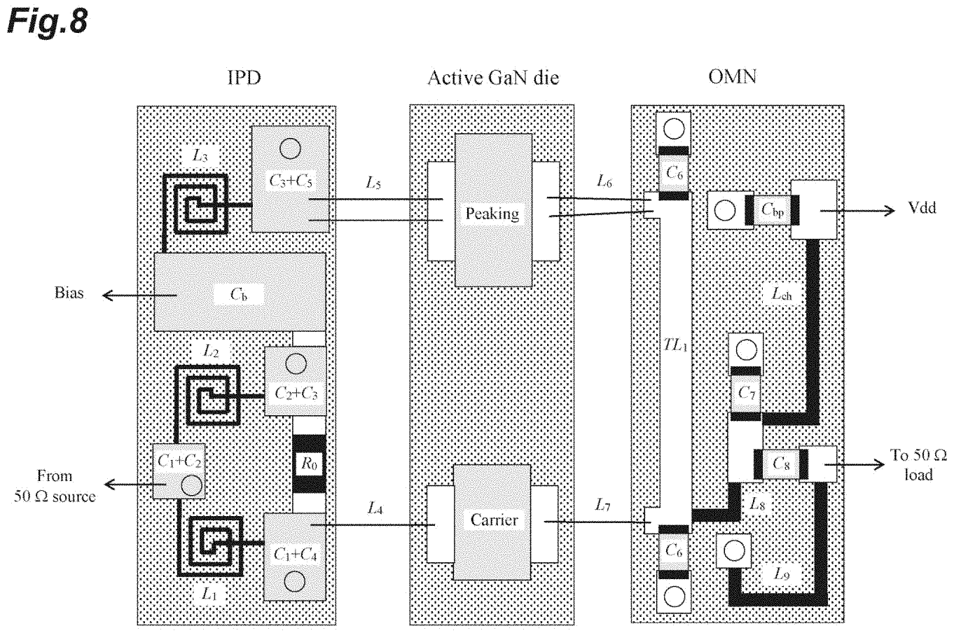

FIG. 8 shows the implementation of the proposed integrated Doherty amplifier where the carrier and peaking devices are located on separate active die using GaN HEMT technology, the integrated passive die (IPD) is used for input circuit including Wilkinson power divider, and the laminate or ceramic OMN is used to implement the output matching circuit.

The key benefits of the IPD technology using gallium arsenide or silicon high-resistivity substrate to implement multiple passive device on a single substrate are a competitive cost structure, a small form factor, and reduced power losses. In view of high dc supply voltage (up to 50 V) and high peak output power (several tens of watt), the best choice for OMN implementation with minimum insertion loss is to use the ceramic or laminate substrate (dielectric substrate).

An input IPD comprises the combined metal-insulator-metal (MIM) series capacitor C₁+C₂, series spiral inductors L₁ and L₂, the combined shunt MIM capacitors C₁+C₄ and C₂+C₃ grounded through substrate vias, the ballast resistor R₀, the blocking series MIM capacitor C_{b}, the series spiral inductor L₃ and the combined shunt MIM capacitor C₃+C₅ grounded through substrate via.

The series bondwire inductors L₄ and L₅ represent the corresponding parts of the input low-pass matching sections directly connected to the gates of the carrier and peaking devices, respectively. An OMN comprises the transmission line TL₁ with two equal shunt capacitors C₆ representing an impedance inverter, the bondwire inductors L₆ and L₇ connected to the drains of the peaking and carrier devices, respectively, operating as the series inductors of the impedance-transforming low-pass matching sections together with the drain-source capacitances C_{ds}, the series inductor L₈ and shunt chip capacitor C₇ (grounded through substrate via) as elements of the low-pass matching section, and the series chip capacitor C₈ and shunt inductor L₉ (grounded through the substrate via) as elements of the high-pass matching section of a two-section output matching network.

The combination of the low-pass and high-pass matching sections in a single matching network operates as an impedance-transforming bandpass filter to suppress the low-frequency and high-frequency intermodulation and harmonic components simultaneously. To improve the quality factors of the inductance and reduce the insertion loss in the output matching network, the series inductor L₈, shunt inductor L₉, and choke inductor L_{ch} are implemented as short-length high-impedance microstrip lines.

As an example, using the laminate substrate with dielectric permittivity of 3.5 and thickness of 0.5 mm, the lengths of the microstrip lines L_{ch} and L₉ using two 20-W GaN HEMT devices for symmetrical Doherty structure (or 15 W and 30 W devices for 1:2 asymmetrical Doherty configuration) are equal to 3.5 mm each, while the width of these microstrip lines are of 0.2 mm at 3.5 GHz.

What is claimed is:

1. A Doherty amplifier including a carrier amplifier and a peak amplifier, comprising:
an input splitter that evenly divides an input radio frequency (RF) signal to the carrier amplifier and the peak amplifier;
an amplifying unit that includes the carrier amplifier and the peak amplifier provided on a semiconductor chip;
an offset unit that includes offset transmission lines each connected with the carrier amplifier and the peak amplifier; and
an output combiner that combines outputs of the carrier amplifier and the peak amplifier each provided through the offset transmission line,
wherein the output combiner and the offset unit that provided on a dielectric substrate;

2. The Doherty amplifier including a carrier amplifier and a peak amplifier to claim 1,
wherein the input splitter provided on another semiconductor chip.

3. The Doherty amplifier including a carrier amplifier and a peak amplifier to claim 1,
wherein one end of the offset transmission line of the offset unit connected with the carrier amplifier and other end of the offset transmission line of the offset unit connected with the peak amplifier by each wire boding.

4. The Doherty amplifier including a carrier amplifier and a peak amplifier to claim 3,
wherein one end of the offset transmission line of the offset unit connected with one end of the output combiner.

5. The Doherty amplifier including a carrier amplifier and a peak amplifier to claim 1,
wherein the offset unit that includes two equal grounded capacitors connected with both ends of the offset transmission line.

6. The Doherty amplifier including a carrier amplifier and a peak amplifier to claim 1,
wherein the transmission line comprises a microstrip line.

7. The Doherty amplifier including a carrier amplifier and a peak amplifier to claim 1,
wherein the input splitter comprises a conductive feature of an integrated passive device (IPD).
